(19) United States
(12) Patent Application Publication
(10) Pub. No.: US 2025/0359320 A1
(43) Pub. Date: Nov. 20, 2025

(54) STACKED TRANSISTORS WITH VERTICALLY STAGGERED CONTACT VIAS

(71) Applicant: INTERNATIONAL BUSINESS MACHINES CORPORATION, ARMONK, NY (US)

(72) Inventors: Debarghya Sarkar, Latham, NY (US); Ruilong Xie, Niskayuna, NY (US); Shay Reboh, Guilderland, NY (US); Abir Shadman, Albany, NY (US); Junli Wang, Slingerlands, NY (US)

(21) Appl. No.: 18/664,926

(22) Filed: May 15, 2024

(51) Int. Cl. H01L 27/092; H01L 21/822; H01L 21/8238; H01L 23/528; H01L 29/06; H01L 29/417; H01L 29/423; H01L 29/66; H01L 29/775

(52) U.S. Cl. CPC H10D 84/856; H10D 30/014; H10D 30/43; H10D 30/6729; H10D 30/6735; H10D 62/121; H10D 84/017; H10D 84/0186; H10D 84/038; H10D 88/01; H01L 23/5286

(57) ABSTRACT

The present disclosure provides a semiconductor structure, a system, and a method of forming a stacked transistor structure with vertically staggered contact vias. The semiconductor structure may include a first stacked transistor cell including a first backside contact having a first contact thickness. The semiconductor structure may also include a second stacked transistor cell including a second backside contact having a second contact thickness different from the first contact thickness. The system may include a semiconductor structure. The method may include forming a first bottom epi and a second bottom epi, filling a first opening in the first stacked transistor cell with one or more metal materials, recessing the one or more metal materials, and filling a second opening in the second stacked transistor cell with the one or more metal materials.

### BACKGROUND

The present disclosure relates to semiconductors and transistors and, more specifically, to stacked field-effect transistors (FETs). Semiconductors, such as complementary metal-oxide-semiconductors (CMOS), are commonly used in computer chips and computer technology. These semiconductor chips/devices typically include transistor(s). Transistors are devices which may be used to switch or amplify electric current or voltage.

FETs use an electric field effect to control current flow within a semiconductor. FETs have three terminals—a source, a drain, and a gate. The source introduces/provides current to the transistor, the drain is the terminal that provides the output current, and the gate is used to control the current flow from the source to the drain. Specifically, FETs use the electric charge of their gates to affect and control the current flow through the channel.

Current flows using charge carriers that are either electrons or holes. Electron charge carriers are negatively charged particles (i.e., electrons) that carry charge and create an electric current. Hole charge carriers (referred to herein as holes) are positions on the FET channel that lack an electron (for instance, at positions of positive charge that is equal in magnitude to the negative charge of an electron and/or positions where an electron could or should be). These holes are positive charges, and they move in an opposite direction of electrons, in some instances. The electric charge and/or voltage of the FET gates is used to control the movements of the electrons and/or holes, which can then affect the current and charge being transmitted through the channel from the source to the drain.

One common type of FET is a nanosheet FET. Nanosheet FETs may have multiple nanosheets stacked (for example, vertically and/or horizontally) above/below each other. The nanosheets act as channels in the FET. In some instances, at least a portion of one or more sides of the nanosheet channels are surrounded by a gate material in nanosheet FETs.

### SUMMARY

The present disclosure provides a semiconductor structure, a system, and a method of forming a stacked transistor structure with vertically staggered contact vias. The semiconductor structure may include a first stacked transistor cell, the first stacked transistor cell including a first backside contact and the first backside contact having a first contact thickness. The semiconductor structure may also include a second stacked transistor cell, the second stacked transistor cell including a second backside contact, the second backside contact having a second contact thickness different from the first contact thickness.

The system may include a semiconductor structure. The semiconductor structure may include a first stacked transistor cell, the first stacked transistor cell having a first contact thickness, where the first stacked transistor cell includes a first backside contact, a first bottom epi, and a first top epi, and where the first backside contact is directly connected to the first bottom epi. The semiconductor structure may also include a second stacked transistor cell, the second stacked transistor cell having a second contact thickness larger than the first contact thickness, where the second transistor cell includes a second backside contact, a second bottom epi, and a second top epi, and where the second backside contact is directly connected to the second bottom epi.

The method may include forming a first bottom epi and a second bottom epi, where a first stacked transistor cell includes the first bottom epi and a second stacked transistor cell includes the second bottom epi. The method may also include filling a first opening in the first stacked transistor cell with one or more metal materials. The method may also include recessing the one or more metal materials, resulting in a first backside contact directly connected to the first bottom epi, the first backside contact having a first contact thickness. The method may also include filling a second opening in the second stacked transistor cell with the one or more metal materials, resulting in a second backside contact directly connected to the second bottom epi, where the second backside contact has a second contact thickness larger than the first contact thickness.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, serve to explain the principles of the disclosure. The drawings are only illustrative of certain embodiments and do not limit the disclosure.

FIG. 1 depicts a cross-sectional view of a semiconductor structure with vertically staggered contact vias, according to some embodiments.

FIG. 2 depicts a cross-sectional view of a first intermediate stage of forming a semiconductor structure with vertically staggered contact vias, according to some embodiments.

FIG. 3 depicts a cross-sectional view of a second intermediate stage of forming a semiconductor structure with vertically staggered contact vias, according to some embodiments.

FIG. 4 depicts a cross-sectional view of a third intermediate stage of forming a semiconductor structure with vertically staggered contact vias, according to some embodiments.

FIG. 5 depicts a cross-sectional view of a fourth intermediate stage of forming a semiconductor structure with vertically staggered contact vias, according to some embodiments.

FIG. 6 depicts a cross-sectional view of a fifth intermediate stage of forming a semiconductor structure with vertically staggered contact vias, according to some embodiments.

FIG. 7 depicts a cross-sectional view of a sixth intermediate stage of forming a semiconductor structure with vertically staggered contact vias, according to some embodiments.

FIG. 8 depicts a cross-sectional view of a seventh intermediate stage of forming a semiconductor structure with vertically staggered contact vias, according to some embodiments.

FIG. 9 depicts a cross-sectional view of an eighth intermediate stage of forming a semiconductor structure with vertically staggered contact vias, according to some embodiments.

FIG. 10 depicts a cross-sectional view of a ninth intermediate stage of forming a semiconductor structure with vertically staggered contact vias, according to some embodiments.

FIG. 11 depicts a cross-sectional view of a tenth intermediate stage of forming a semiconductor structure with vertically staggered contact vias, according to some embodiments.

FIG. 12 depicts a cross-sectional view of an eleventh intermediate stage of forming a semiconductor structure with vertically staggered contact vias, according to some embodiments.

FIG. 13 depicts a cross-sectional view of a twelfth intermediate stage of forming a semiconductor structure with vertically staggered contact vias, according to some embodiments.

FIG. 14 depicts a cross-sectional view of a thirteenth intermediate stage of forming a semiconductor structure with vertically staggered contact vias, according to some embodiments.

FIG. 15 depicts a cross-sectional view of a fourteenth intermediate stage of forming a semiconductor structure with vertically staggered contact vias, according to some embodiments.

FIG. 16 depicts a cross-sectional view of a fifteenth intermediate stage of forming a semiconductor structure with vertically staggered contact vias, according to some embodiments.

FIG. 17 depicts a cross-sectional view of a second example semiconductor structure with vertically staggered contact vias, according to some embodiments.

FIG. 18 depicts a cross-sectional view of a third example semiconductor structure with vertically staggered contact vias, according to some embodiments.

FIG. 19 depicts a flowchart of an example method of forming a semiconductor structure with vertically staggered contact vias, according to some embodiments.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

Aspects of the present disclosure relate to semiconductors and transistors and, more specifically, to stacked field-effect transistors (FETs) with vertically staggered contact vias. While the present disclosure is not necessarily limited to such applications, various aspects of the disclosure may be appreciated through a discussion of various examples using this context.

Transistors, such as field-effect transistors (FETs), may be used within a system (for example, within a semiconductor structure) to switch or amplify electric current or voltage. FETs may have two typical configurations, N-channel FETs and P-channel FETs. N-channel FETs introduce (for example, through doping) an n-type impurity to the semiconductor material of the source and the drain, and P-channel FETs introduce a p-type impurity to the semiconductor material of the source and the drain.

For n-type impurities, arsenic, phosphorous, or any other n-type material may be added to the silicon. N-type materials may have five electrons in their outer orbitals. When the n-type materials are combined with the silicon of the semiconductor, the fifth electron may not have anything to bond to and may freely move around, which may allow an electric current to flow through the silicon semiconductor channel. Because there are extra electrons from the n-type materials, the majority carriers/charge carriers for N-channel FETs are electrons.

In P-channel FETs, p-type impurities such as boron, gallium, etc., may be added to the silicon semiconductor(s) for the silicon doping. The p-type materials may have three electrons in their outer orbitals which, when added to silicon, may form holes (i.e., may lack electrons) in the valence bonds of the silicon atoms. Because there are holes in the valence bonds due to the p-type materials, the majority carriers/charge carriers for P-channel FETs are holes. An N-channel FET may be referred to herein as an NFET and a P-channel FET may be referred to herein as a PFET.

In some instances, it may be beneficial to have multiple FETs connected to each other. For example, in logic gate designs, an N-gate from an NFET may be electrically connected to a P-gate from a PFET in order to form an input for the logic gate. A logic gate may be a circuit with one or more inputs (for example, any number of inputs), but only one output. In some instances, for example, combining NFET and PFET in a logic gate design can eliminate large current leakage from VDD (a positive supply voltage) to ground in a static/non-switching period, as one of the transistors will be off which may prevent different shorts between VDD and ground. This design is conventionally referred to as a complementary metal-oxide-semiconductor (CMOS) logic design. Because of the benefits of combining NFET and PFET in a logic gate design, various logic designs may include NFET-PFET pairs.

As technology has advanced, it has become increasingly beneficial to have large amounts of technology and components in very small spaces. Reducing the size of the technology and components may be referred to herein as scaling. One method of scaling to help fit components in a small area, without reducing the capabilities of the components, is to stack transistors. Stacking transistors may increase the thickness of the semiconductor chip/semiconductor structure, but may reduce the area on the chip taken up by transistors. This may help allow for more components on the surface of a chip and/or may allow for a smaller chip, in some instances. For example, for logic gate designs, the connected NFET and PFET may be stacked on top of each other in order to have the benefit of the NFET-PFET pair (discussed above) while also saving space and reducing the area on the chip taken up by the NFET and PFET.

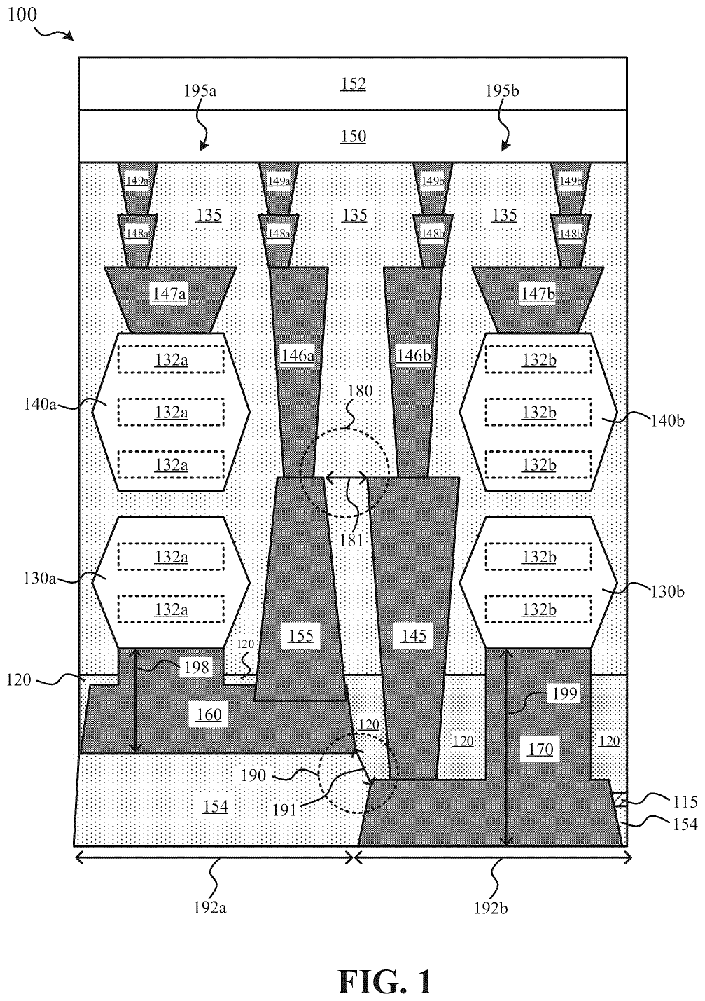

In some instances, stacking transistors may create space for multiple stacked transistor sets (also referred to herein as stacked transistor cells) to fit on the same semiconductor chip/structure. This may help increase processing power, speed, etc. of the semiconductor chip, thus improving the functioning of the semiconductor chip. However, various issues may occur as semiconductor structures and stacked transistor cell heights continue to get increasingly smaller. “Transistor cell heights,” or “cell heights,” is intended to be used herein consistently with industry usage, and refers to a measurement of a distance taken up by a cell in a dimension that is parallel to a wiring layer. This is made clear in the descriptions of FIGS. 1-19, but it is important to note that a “cell height” is depicted as a lateral/horizontal dimension in the cross sections illustrated in FIGS. 1-19 for the purposes of ease of presentation.

For instance, as more stacked transistor cells are added to the same semiconductor chip/structure, the closeness of the stacked transistor cells and their components can cause shorts (for example, electrical shorts). Specifically, contact vias for the stacked transistor cells can have areas where they are too close together (e.g., too close to other contact vias) which causes shorting. For example, because the contact vias are made of metal, even if they are not directly connected to each other if the contact vias are too close together they can still transmit heat and/or current, thus causing shorts. The contact via areas/points that are too close together may be referred to herein as failure points.

The present disclosure relates to semiconductors and transistors and, more specifically, to stacked field-effect transistors (FETs) with vertically staggered contact vias. To help prevent issues, such as shorts, caused by failure points of the contact vias (i.e., points/areas where the contact vias are too close together), stacked FETs with staggered contact vias are discussed herein. Specifically, the contact vias for adjacent stacked transistor cells (i.e., transistor cells that are directly next to each other) may be staggered such that the contact vias are not positioned in a same and/or mirror structure of the adjacent stacked transistor cell. In some instances, one or more of the contact vias may be in a flipped and/or inverted orientation (compared to the adjacent stacked transistor cell contact via(s)) to further distance the contact vias and prevent failure points. Because of the new angles and distances between contact vias (for adjacent stacked transistor cells) caused by the staggering and, in some instances, flipping/inverting of the contact via(s), the space between contact vias is increased which helps prevent failure points and shorts within the semiconductor structure.

Additionally, staggering and/or flipping/inverting contact via(s) helps prevent any increase in cell height or reduction in contact via dimensions. For instance, conventional semiconductor devices may increase cell height, increase chip size, and/or reduce the size/dimensions of the contact via(s) in order to try and prevent failure points. However, increasing the cell height and/or semiconductor chip size may reduce and/or prevent scaling of the semiconductor structure, as instead of decreasing the size of the stacked transistor cell(s) and semiconductor chip(s), the size may be increased. Further, reducing the size/dimensions of the contact via(s) may make the contact vias less effective due to the smaller size. By staggering and/or inverting contact via(s), the contact vias are able to be distanced from each other (thus reducing and/or preventing failure points between the contact vias) without reducing the size of the contact vias nor increasing the size of the stacked transistor cells, which helps maintain the scalability of the semiconductor structure(s), stacked transistor cells, etc. Put differently, staggering and/or inverting contact via(s) helps reduce and/or prevent failure points and shorts without compromising or reducing semiconductor structure functionality due to lack of scaling ability and/or undesired decrease in contact via sizing.

According to an aspect of the invention, there is provided a semiconductor structure, where the semiconductor structure includes a first stacked transistor cell, the first stacked transistor cell including a first backside contact and the first backside contact having a first contact thickness; and a second stacked transistor cell, the second transistor cell including a second backside contact, the second backside contact having a second contact thickness different from the first contact thickness. In some embodiments, the second stacked transistor cell is adjacent to the first stacked transistor cell. In some instances, the vertical staggering of the first backside contact and the second backside contact can serve to improve spacing between the first and second backside contacts, prevent failure points, and prevent shorting, thus helping improve the functioning of the semiconductor structure.

In some embodiments, the first stacked transistor cell further includes an inverted backside contact via in a first orientation, the second stacked transistor cell further includes a contact via in a second orientation, and the first orientation is inverted compared to the second orientation. In some instances, the inverted backside contact via and its inverted orientation compared to the second orientation can serve to improve spacing between the inverted backside contact via and the contact via, prevent failure points, and prevent shorting, as the thickest portions of the inverted backside contact via and the contact via may not be directly next to each other.

In some embodiments, the contact via is a frontside contact via. In some instances, the use of a frontside contact via and an inverted backside contact via can help create/establish the inverted orientation of the backside contact via compared to the frontside contact via.

In some embodiments, the inverted backside contact via is directly connected to the first backside contact, and the contact via is directly connected to the second backside contact. In some embodiments, the inverted backside contact via is directly connected to a second contact via, the second contact via having a third orientation; and the third orientation is a same orientation as the second orientation. In some instances, the use of various contacts and contact vias may help connect epis (e.g., top epis and/or bottom epis) to various other components in the semiconductor structure.

In some embodiments, the second contact thickness is smaller than the first contact thickness. In some embodiments, the second contact thickness is larger than the first contact thickness. In some instances, different contact thicknesses of the first and second backside contacts can help vertically stagger the first and second backside contacts, which can serve to improve spacing, prevent failure points, and prevent shorting.

In some embodiments, the first stacked transistor cell further includes a first top epi and a first bottom epi, and the second stacked transistor cell further includes a second top epi and a second bottom epi. In some embodiments, the first backside contact is directly connected to the first bottom epi, and the second backside contact is directly connected to the second bottom epi. In some instances, the use of various contacts and/or contact vias may help connect epis (e.g., top epis and/or bottom epis) to various other components in the semiconductor structure.

In some embodiments, the first transistor cell and the second transistor cell further include one or more nanosheets. In some instances, in stacked transistor structures such as nanosheet stacked transistor structures, vertical contact staggering may help improve/increase scaling of the semiconductor structure.

According to an aspect of the invention, there is provided a system, where the system includes a semiconductor structure, where the semiconductor structure includes a first stacked transistor cell, the first stacked transistor cell having a first contact thickness, where the first stacked transistor cell includes a first backside contact, a first bottom epi, and a first top epi, and where the first backside contact is directly connected to the first bottom epi; and a second stacked transistor cell, the second stacked transistor cell having a second contact thickness larger than the first contact thickness, where the second transistor cell includes a second backside contact, a second bottom epi, and a second top epi, and where the second backside contact is directly connected to the second bottom epi. In some instances, the vertical staggering of the first backside contact and the second backside contact can serve to improve spacing between the first and second backside contacts, prevent failure points, and prevent shorting, thus helping improve the functioning of the semiconductor structure.

In some embodiments, the first stacked transistor cell further includes an inverted backside contact via in a first orientation, the second stacked transistor cell further includes a contact via in a second orientation, and the first orientation is inverted compared to the second orientation. In some instances, the inverted backside contact via and its inverted orientation compared to the second orientation can serve to improve spacing between the inverted backside contact via and the contact via, prevent failure points, and prevent shorting, as the thickest portions of the inverted backside contact via and the contact via may not be directly next to each other.

In some embodiments, the contact via is a frontside contact via. In some instances, the use of a frontside contact via and an inverted backside contact via can help create/establish the inverted orientation of the backside contact via compared to the frontside contact via.

In some embodiments, the inverted backside contact via is directly connected to the first backside contact, and the contact via is directly connected to the second backside contact. In some embodiments, the system further includes an interconnect, where the bottom epi is connected to the interconnect through at least the first backside contact and the inverted backside contact. In some embodiments, the inverted backside contact via is directly connected to a second contact via, the second contact via having a third orientation; and the third orientation is a same orientation as the second orientation. In some instances, the use of various contacts and contact vias may help connect epis (e.g., top epis and/or bottom epis) to various other components in the semiconductor structure, such as an interconnect.

In some embodiments, the first stacked transistor cell further includes a contact via in a first orientation, the second stacked transistor cell further includes an inverted backside contact via in a second orientation, and the second orientation is inverted compared to the first orientation. In some embodiments, the contact via is directly connected to the first backside contact, and the inverted backside contact is directly connected to the second backside contact. In some instances, the inverted backside contact via and its inverted orientation compared to the first orientation can serve to improve spacing between the inverted backside contact via and the contact via, prevent failure points, and prevent shorting, as the thickest portions of the inverted backside contact via and the contact via may not be directly next to each other.

According to an aspect of the invention, there is provided a method of forming a semiconductor structure, the method including forming a first bottom epi and a second bottom epi, where a first stacked transistor cell includes the first bottom epi and a second stacked transistor cell includes the second bottom epi; filling a first opening in the first stacked transistor cell with one or more metal materials; recessing the one or more metal materials, resulting in a first backside contact directly connected to the first bottom epi, the first backside contact having a first contact thickness; and filling a second opening in the second stacked transistor cell with the one or more metal materials, resulting in a second backside contact directly connected to the second bottom epi, where the second backside contact has a second contact thickness larger than the first contact thickness. In some instances, the vertical staggering of the first backside contact and the second backside contact can serve to improve spacing between the first and second backside contacts, prevent failure points, and prevent shorting, thus helping improve the functioning of the semiconductor structure.

Referring now to FIG. 1, a cross-sectional view of a semiconductor structure 100 with vertically staggered contact vias is depicted, according to some embodiments. The cross-sectional views depicted in FIGS. 1-19 are cross-section(s) parallel to the gate regions and in a source/drain (S/D) epi region of a semiconductor structure.

Semiconductor structure 100 includes a frontside interconnect 150 and a carrier wafer 152. In some instances, frontside interconnect 150 may be a back end of line (BEOL) interconnect. Frontside and backside, as referred to herein, may refer to the frontside and backside of a semiconductor die/chip. In some instances, the carrier wafer 152 may contain silicon (Si). In some instances, the frontside interconnect 150 may be described as directly contacting, directly connected to, directly below (when viewing from the cross-section depicted in FIG. 1), etc. the carrier wafer 152. Similarly, the carrier wafer 152 may be described as directly contacting, directly connected to, directly above (when viewing from the cross-section depicted in FIG. 1), etc. the frontside interconnect 150. Below, above, on top of, etc. may refer to components (such as transistors) and their positions when looking at a cross-sectional view such as the views depicted in FIGS. 1-19.

As depicted in FIG. 1, semiconductor structure 100 includes a plurality of S/D epitaxies (epis) 130a, 130b, 140a, and 140b. S/D epis 130a and 130b may be referred to herein as bottom epis 130a and 130b (collectively, bottom epis 130) as they are the epis for the bottom transistors in the sets of stacked transistors 195a and 195b. S/D epis 140a and 140b may be referred to herein as top epis 140a and 140b (collectively, top epis 140) as they are the epis for the top transistors in the sets of stacked transistors 195a and 195b. In some instances, the top epis 140 and the bottom epis 130 may correspond to a first type of transistors and a second type of transistors, respectively. For example, the top epis 140 may be PFET epis (referred to herein as P-epis) and the bottom epis 130 may be NFET epis (referred to herein as N-epis). In some instances, epis 130 and 140 may be materials such as silicon germanium (SiGe), silicon (Si), silicon carbide (SiC), etc. In some instances, top epis 140 and bottom epis 130 may be different materials. For instance, the epi materials may correspond to the type of transistor (e.g., NFET or PFET). In some instances, PFETs may include epi materials such as boron-doped or gallium-doped SiGe, and NFETs may include epi materials such as phosphorous-doped or arsenic-doped Si or SiC. Therefore, for example, when the top epis 140 are P-epis and the bottom epis 130 are N-epis, top epis 140 may be boron- or gallium-doped SiGe and bottom epis 130 may be phosphorous- or arsenic-doped Si or SiC.

In some instances, the sets of stacked transistors 195a and 195b are nanosheet transistors, and each transistor comprises nanosheets 132a and/or nanosheets 132b (referred to collectively as nanosheets 132). In some instances, the top transistors (corresponding to top epis 140) may include three or more nanosheets 132 and the bottom transistors (corresponding to bottom epis 130) may include two or more nanosheets 132. In some instances, although FIG. 1 depicts the bottom transistors having two nanosheets 132 and the top transistors having three nanosheets 132, each transistor may include any number of nanosheets 132.

In some instances, although FIG. 1 depicts nanosheets 132, the nanosheets 132 may not be visible from the cross-sections depicted in FIGS. 1-19. Therefore, nanosheets 132 are depicted with a dotted line to help indicate that they may not actually be visible from the depicted cross-section and are instead exemplary to help show the nanosheets 132 position within the sets stacked transistors 195a and 195b.

As discussed herein, semiconductor structure 100 includes a first set of stacked transistors 195a and a second set of stacked transistors 195b. Each set of stacked transistors 195a and 195b (referred to collectively as set(s) of stacked transistors 195) includes a top transistor with a top epi 140 and a bottom transistor with a bottom epi 130, as well as various contacts and contact vias (discussed further herein). Specifically, the set of stacked transistors 195a may include conducting wires 149a, contact vias 148a, contact 147a, top epi 140a, nanosheets 132a, contact via 146a, backside contact via 155, backside contact 160, and bottom epi 130a. The set of stacked transistors 195b may include conducting wires 149b, contact vias 148b, contact 147b, top epi 140b, nanosheets 132b, contact via 146b, contact via 145, backside contact 170, and bottom epi 130b. In some instances, each set of stacked transistors 195a and 195b may also include various dielectrics, such as backside interlayer dielectric (BILD) 154, dielectric layer 115, dielectric 120, and dielectric 135. The various dielectrics (BILD 154, dielectric layer 115, dielectric 120, and dielectric 135) may be dielectric materials such as silicon nitride (SiN), silicon dioxide (SiO₂), other oxide(s), silicoboron carbonitride (SiBCN), silicon oxycarbonitride (SiOCN), silicon carbide (SiC), silicon oxycarbide (SiOC), etc. In some instances, the dielectrics (BILD 154, dielectric layer 115, dielectric 120, and dielectric 135) may be different materials. For example, BILD 154 may contain an oxide, dielectric layer 115 may contain a nitride, and/or dielectric 120 may contain an oxide different than BILD 154. In this example, dielectric 135 may contain a different dielectric material(s) than BILD 154 and dielectric 120 in some instances, or, in other instances, may contain a same dielectric material(s) as BILD 154.

In some instances, the sets of stacked transistors 195a and 195b may be referred to herein as stacked transistor cells 195a and 195b. A stacked transistor cell refers to a single set of stacked transistors (i.e., a transistor stacked on top of another transistor) and their corresponding components. For example, a stacked transistor cell may include two transistors—one stacked on top of the other. Each stacked transistor cell (195a and 195b) has a cell height (192a and 192b) (discussed further herein). Although cell heights 192a and 192b (collectively 192) are illustrated as lateral dimensions when viewing from the cross-section depicted in FIG. 1, the term “cell heights” is used to be consistent with industry nomenclature. In some instances, stacked transistor cells 195a and 195b are referred to collectively as stacked transistor cells 195. Although FIG. 1 depicts two stacked transistor cells—195a and 195b—semiconductor structure 100 may include any number of stacked transistor cells. In some instances, semiconductor structure 100 includes a plurality of stacked transistor cells.

Stacked transistor cells 195a and 195b may be referred to herein as adjacent stacked transistor cells, as they are stacked transistor cells that are directly next to each other and do not have any other transistor cells between them. In some instances, adjacent stacked transistor cells (such as stacked transistor cells 195a and 195b) may only be separated by dielectric material(s) (e.g., dielectric 135, 120, and 154).

As depicted in FIG. 1, the semiconductor structure 100 includes various contacts and contact vias. The various contacts and contact vias in each stacked transistor cell 195 are used to help connect each transistor and its components (for example, top epis 140 and bottom epis 130) to the frontside interconnect 150. Specifically, semiconductor structure 100 includes contacts 147 (i.e., 147a and 147b, collectively 147), conducting wires 149 (i.e., 149a and 149b, collectively 149), contact vias 148 (i.e., 148a and 148b, collectively 148), contact vias 146 (i.e., 146a and 146b, collectively 146), contact via 145, contact via 155, backside contact 160, and backside contact 170. In some instances, conducting wires 149, contact vias 148, contact vias 146, contact via 145, contact via 155, backside contact 160, and backside contact 170 may be metal contacts and/or vias, and may be metal material(s) such as cobalt (Co), tungsten (W), copper (Cu), ruthenium (Ru), etc. In some instances, conducting wires 149, contact vias 148, contact vias 146, contact via 145, contact via 155, backside contact 160, and backside contact 170 may all be the same material(s). In some instances, one or more of conducting wires 149, contact vias 148, contact vias 146, contact via 145, contact via 155, backside contact 160, and backside contact 170 may be different material(s).

Contacts, conducting wires, and contact vias may be various types of connections between components of the semiconductor structure 100. In some instances, contacts and conducting wires may be connections between a contact or contact via and another component of the semiconductor structure (such as an interconnect or an epi). For instance, conducting wires 149 connect contact vias 148 to interconnect 150 and backside contacts 160 and 170 connect bottom epis 130 to contact vias 155 and 145, respectively. Contact vias, as referred to herein, are connections between contacts, conducting wires, and/or contact vias (e.g., a connection between a first and second contact, a connection between a contact and a contact via, a connection between a contact via and a conducting wire, a connection between a first and second contact via, etc.). For instance, contact vias 148 connect contact vias 146 and/or contacts 147 to conducting wires 149. Contact vias 155 and 145 connect backside contacts 160 and 170, respectively, to contact vias 146. Contact vias are referred to herein as contact vias to help distinguish from a via that is an opening and/or hole.

In semiconductor structure 100, the top epis 140 are connected to the frontside interconnect 150 through contacts 147, contact vias 148, and conducting wires 149. Specifically, contacts 147 connect top epis 140 to contact vias 148, contact vias 148 connect contacts 147 to conducting wires 149, and conducting wires 149 connect contact vias 148 to frontside interconnect 150. The bottom epis 130 are connected to the frontside interconnect 150 through backside contacts 160/170, backside contact via 155/contact via 145, contact vias 146, contact vias 148, and conducting wires 149. In some instances, top epis 140 may be described as directly connected to contacts 147 (and vice versa), contacts 147 may be described as directly connected to contact vias 148 (and vice versa), contact vias may be described as directly connected to conducting wires 149 (and vice versa), conducting wires 149 may be described as directly connected to frontside interconnect 150, contact vias 146 may be described as directly connected to contact vias 148 (and vice versa), contact via 155 may be described as directly connected to contact via 146 (and vice versa), contact via 145 may be described as directly connected to contact via 146 (and vice versa), backside contact 160 may be described as directly connected to backside contact via 155 (and vice versa), backside contact 170 may be described as directly connected to contact via 145 (and vice versa), etc. In some instances, conducting wires 149 are metal 1 (M1) contacts.

As discussed herein, transistor components and transistor cells (such as stacked transistor cells 195) continue to get closer together, and the space between the transistor cells is reduced, as technology advances and devices continue to get smaller. However, when stacked transistor cells and their components (particularly their contacts and contact vias) get closer together, the closeness of the metal contacts and contact vias can cause shorts (such as electrical shorts). In semiconductor structure 100, the areas where the stacked transistor cells 195 and their corresponding contacts/contact vias are closest together are areas 180 and 190. However, to prevent areas 180 and 190 from becoming failure points and causing shorts, semiconductor structure 100 includes staggered contacts and inverted contacts. Specifically, in semiconductor structure 100, backside contacts 160 and 170 are staggered from each other (i.e., are not in line with each other). Staggered contacts, as referred to herein, are contacts that are not in line with each other and are not exact mirrors of each other, and are instead staggered/tiered. For example, in semiconductor structure 100, the base of backside contact 160 is above the base of backside contact 170. Therefore, backside contact 160 and backside contact 170 are staggered from each other and backside contact 160 is staggered/tiered above backside contact 170. This staggering may also be referred to herein as vertical staggering, as the backside contacts 160 and 170 are staggered from each other in a vertical direction (for instance, when viewing from the cross-section depicted in FIG. 1).

In some instances, to achieve the vertical staggering of backside contacts 160 and 170, backside contact 160 has a thickness 198 smaller than the thickness 199 of backside contact 170. Thicknesses 198 and 199 are referred to herein as contact thicknesses 198 and 199 to help distinguish from cell heights 192, though contact thicknesses 198 and 199 are vertical dimensions when viewing from the cross-section depicted in FIG. 1. Cell heights 192, as discussed herein, are lateral/horizontal dimensions when viewing from the cross-section depicted in FIG. 1. By having backside contact 160 with a contact thickness 198 smaller than the contact thickness 199 of backside contact 170, backside contact 160 and backside contact 170 are staggered. Because the dimension in which backside contacts 160 and 170 are staggered is displayed as a vertical dimension in FIG. 1, this staggering may sometimes be referred to herein as a “vertical staggering.” This may also be described as contacts 160 and 170 being staggered such that a bottom surface of backside contact 160 is closer to frontside interconnect 150 (or carrier wafer 152) than a bottom surface of backside contact 170.

By vertically staggering the backside contacts 160 and 170, the distance 191 between the backside contacts 160 and 170 remains far enough apart to prevent any shorting and/or failure points. Area 190 is one of the areas in the semiconductor structure 100 where the metal components (in this instance, backside contacts 160 and 170) may be closest together and may be an area that would have been susceptible to becoming a failure point if the backside contacts 160 and 170 were not vertically staggered.

Another area in semiconductor structure 100 where the metal components (in this instance, backside contact via 155 and contact via 145) are closest together is area 180. To prevent any failure points and shorts, backside contact via 155 has been flipped/inverted. For instance, contact via 145 may be referred to as having a first structure with a thickest area of the contact via 145 at the top portion of the contact via 145 structure and a thinnest area of the contact via 145 at a bottom portion of the contact via 145 structure (when viewing from the cross-section depicted in FIG. 1). Backside contact via 155 may have a second structure that is inverted/flipped when comparing it to the first structure of contact via 145, as backside contact via 155 has a thinnest area of the contact via at the top portion of the backside contact via 155 structure and a thickest area of the contact via at a bottom portion of the backside contact via 155 structure (when viewing from the cross-section depicted in FIG. 1).

By inverting backside contact via 155, the thickest areas of each of the contact vias (145 and 155) are not right next to each other (which could cause a failure point due to the closeness). Instead, the thinnest portion of backside contact via 155 is in line with the thickest portion of contact via 145, creating a distance 181 between the contact vias (145 and 155) that is large enough to be not susceptible to shorting, thus preventing a potential failure point. Further, because of the increased spacing in areas 180 and 190 and the preventing of shorting between the corresponding contacts 160 and 170 and/or contact vias 145 and 155, semiconductor structure 100 can be scaled smaller than conventional semiconductor structures. For example, in some instances, each stacked transistor cell 195 can have a cell height 192 of two M1 pitches (e.g., the distance between two M1 lines).

In some instances, although FIG. 1 depicts conducting wires 149, contact vias 148, contact vias 146, contact via 145, backside contact via 155, backside contact 160, and backside contact 170, semiconductor structure 100 may include any number of contacts and/or contact vias.

Additionally, although various components of the semiconductor structure 100 (for example, backside contact 160 and backside contact via 155, backside contact 170 and contact via 145, etc.) are depicted as separate entities in FIG. 1 (for instance, due to the possibility of different materials as well as for clarity in future intermediate stages), these various components may not actually be separate entities.

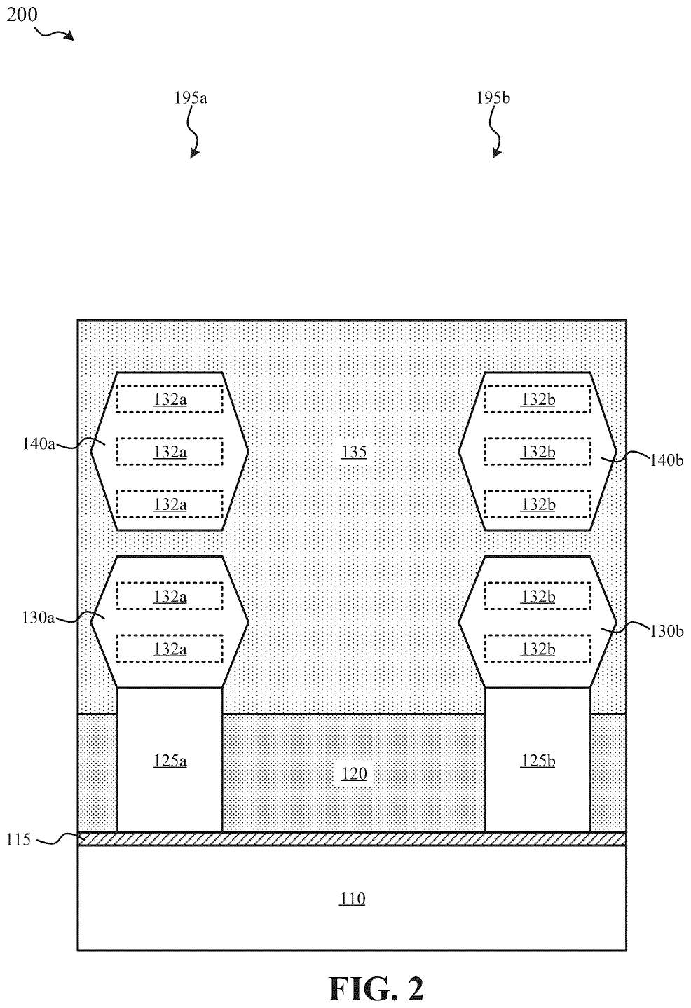

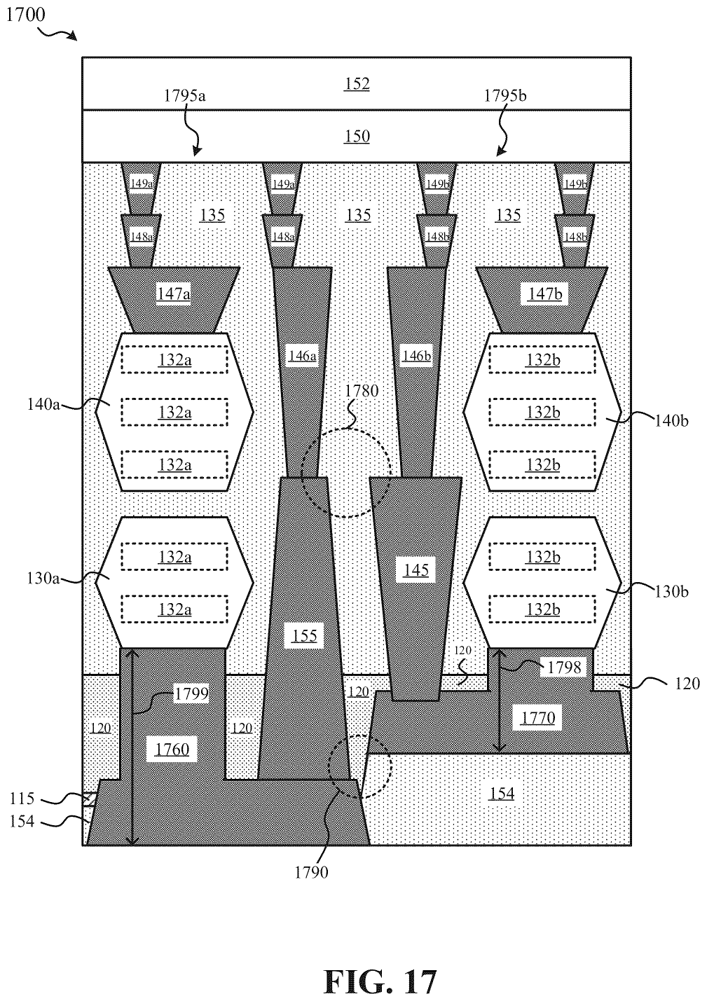

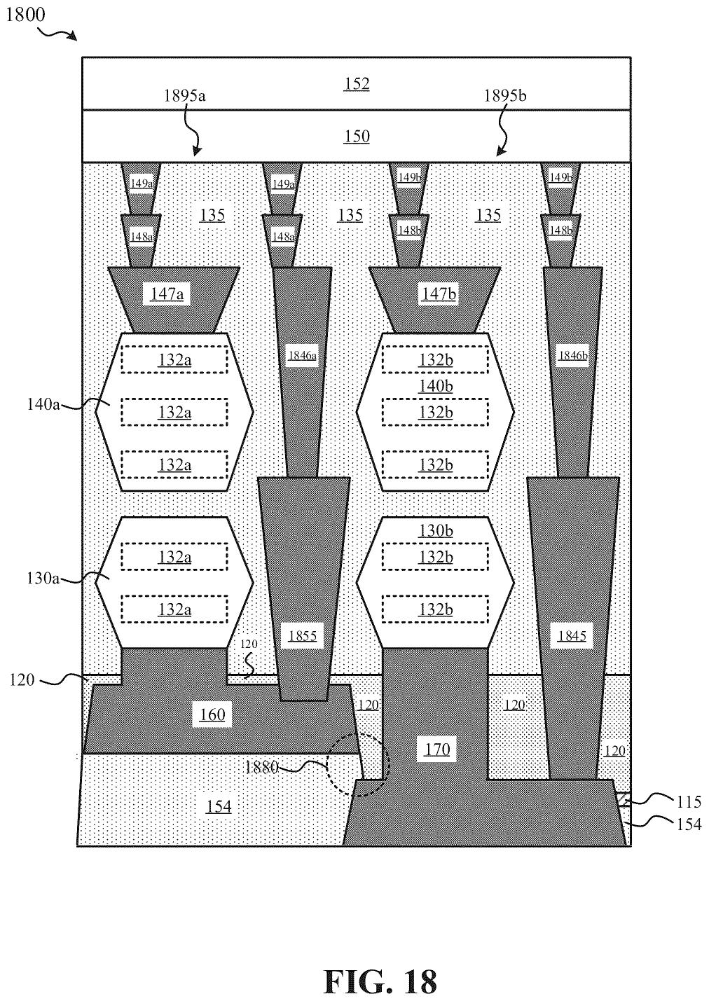

FIGS. 2-16 depict intermediate stages in the process of forming semiconductor structure 100 (FIG. 1), according to some embodiments. Further, although FIGS. 2-16 are described herein as forming semiconductor structure 100 (FIG. 1), the same/similar steps may be used to form semiconductor structure 1700 (FIG. 17) and/or semiconductor structure 1800 (FIG. 18). FIGS. 2-18 are depicted from a cross-sectional view in a S/D region of the semiconductor structure(s).

Referring now to FIG. 2, a cross-sectional view of an intermediate stage 200 of forming a semiconductor structure with vertically staggered contact vias is depicted, according to some embodiments. Intermediate stage 200 includes top epis 140, bottom epis 130, nanosheets 132, dielectric 135, dielectric 120, and dielectric layer 115. In some instances, top epi 140a, bottom epi 130a, and nanosheets 132a are all a part of a first stacked transistor cell 195a, and top epi 140b, bottom epi 130b, and nanosheets 132b are all a part of a second stacked transistor cell 195b.

In some instances, as discussed in relation to FIG. 1, dielectric 135 and dielectric 120 may be different dielectric materials, in some instances. In some instances, dielectric 120 may be shallow trench isolation (STI). In some instances, dielectric layer 115 may serve as an etch stop layer.

In some instances, as depicted in FIG. 2, intermediate stage 200 further includes a substrate 110 (e.g., a silicon (Si) substrate) below the dielectric layer 115, as well as dummy contacts 125a and 125b (collectively, dummy contacts 125). Dummy contacts 125 may be dummy layers/components that act as placeholders for later formed contacts. In some instances, dummy contacts 125 are silicon germanium (SiGe).

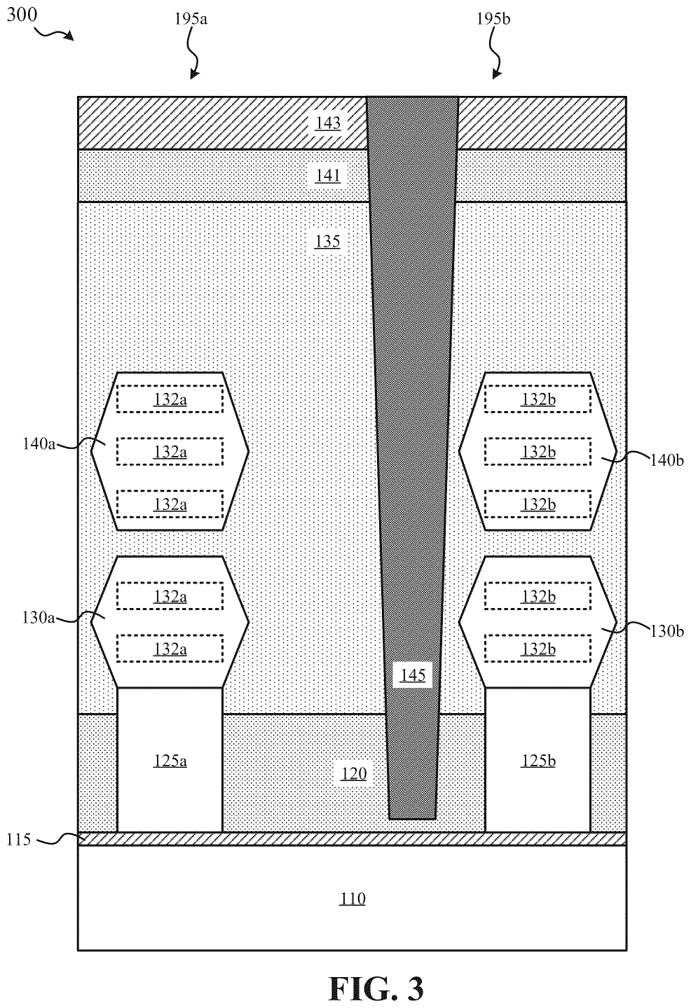

Referring to FIG. 3, a cross-sectional view of an intermediate stage 300 of forming a semiconductor structure with vertically staggered contact vias is depicted, according to some embodiments. In intermediate stage 300, dielectric layers 141 and 143 are deposited on top of/above dielectric 135. Dielectric layers 141 and 143 may be deposited through methods such as atomic layer deposition (ALD), chemical vapor deposition (CVD), laser induced chemical vapor deposition (LCVD), and/or any other deposition technique. In some instances, dielectric layer 141 is material(s) the same/similar to dielectric 120. In some instances, dielectric layer 143 is material(s) the same/similar to dielectric layer 115. Dielectric layers 141 and 143 may help protect dielectric 135 from any unwanted etching.

In some instances, intermediate stage 300 further includes patterning/etching an opening (not depicted) through dielectric layer 143, dielectric layer 141, dielectric 135, and dielectric 120, the opening ending in dielectric 120 and above dielectric layer 115. The opening may be patterned/etched through reactive ion etching (RIE), ion beam etching (IBE), and/or any other patterning/etching process. Once an opening has been created, a metal fill may be performed to fill the opening with metal material(s) 145. These metal material(s) 145 are referred to herein as contact via 145, as it functions as a contact via 145 within the semiconductor structure (e.g., semiconductor structure 100 (FIG. 1)). The metal material(s)/contact via 145 may be deposited/filled through methods such as atomic layer deposition (ALD), chemical vapor deposition (CVD), laser induced chemical vapor deposition (LCVD), and/or any other deposition technique. In some instances, contact via 145 is metal material(s) such as Co, W, Cu, Ru, etc. In some instances, contact via 145 is a frontside contact via, as it is formed in/through the frontside of the semiconductor structure (as depicted in FIG. 3).

As depicted in FIG. 3, the contact via 145 is only formed for one stacked transistor cell (in this instance, stacked transistor cell 195b). This is because, as discussed herein, the contact/contact via structures are not identical and/or mirrored for the adjacent stacked transistor cells 195a and 195b in order to help prevent shorts and to help improve scaling of the semiconductor structure.

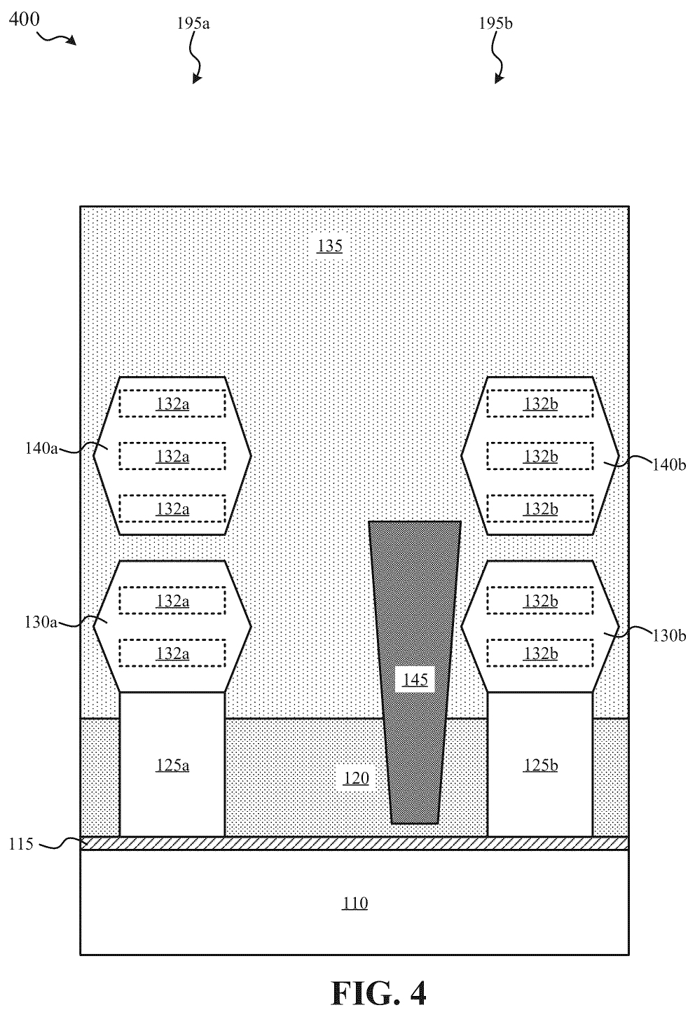

Referring now to FIG. 4, a cross-sectional view of an intermediate stage 400 of forming a semiconductor structure with vertically staggered contact vias is depicted, according to some embodiments. In intermediate stage 400, contact via 145 is recessed and the resulting opening (not depicted) is filled with dielectric 135. Further, dielectric layers 143 and 141 are removed (for example, through chemical mechanical planarization (CMP)). In some instances, contact via 145 may be recessed (i.e., a portion of contact via 145 is removed) through patterning/etching processes such as RIE, IBE, and/or any other patterning/etching process.

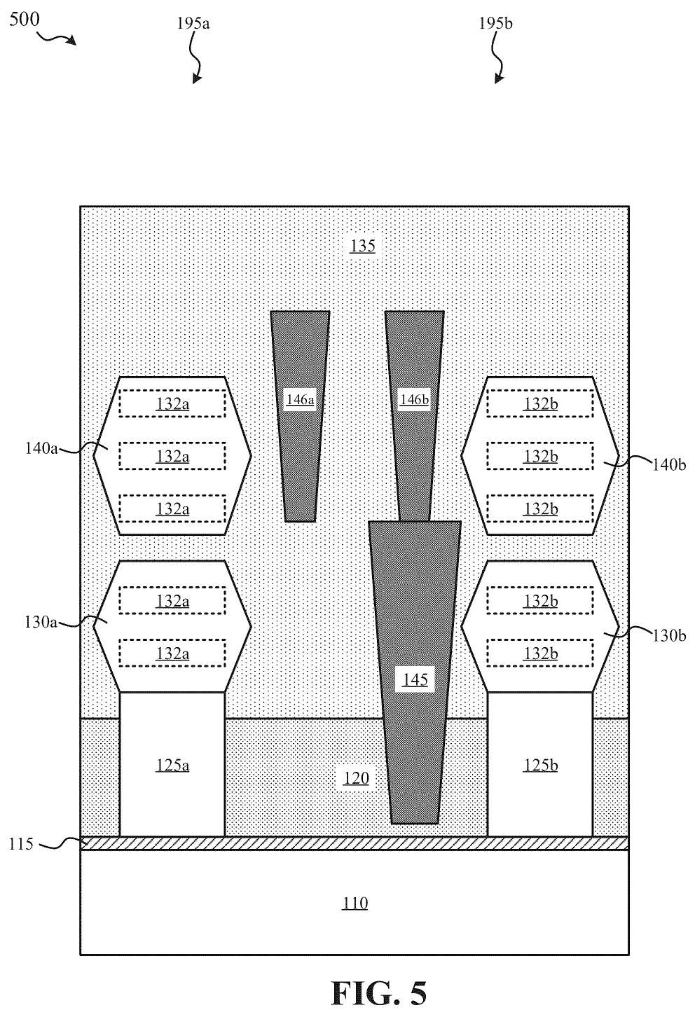

Referring to FIG. 5, a cross-sectional view of an intermediate stage 500 of forming a semiconductor structure with vertically staggered contact vias is depicted, according to some embodiments. Intermediate stage 500 includes forming contact vias 146a and 146b (collectively, 146). Contact vias 146 may be formed, in some instances, by patterning/etching openings in dielectric 135, performing a metal fill to fill the openings with metal material(s), recessing the metal, and filling the resulting openings with dielectric 135. This may be similar to intermediate stages 300 (FIG. 3) and 400 (FIG. 4), in some instances.

As depicted in FIG. 5, contact vias 146 may be formed in both stacked transistor cells 195a and 195b. This is because the contact vias 146 may not cause any points of concern or critical points that may cause shorting, therefore the contact vias 146 may be formed using the same/similar steps for both stacked transistor cells 195a and 195b.

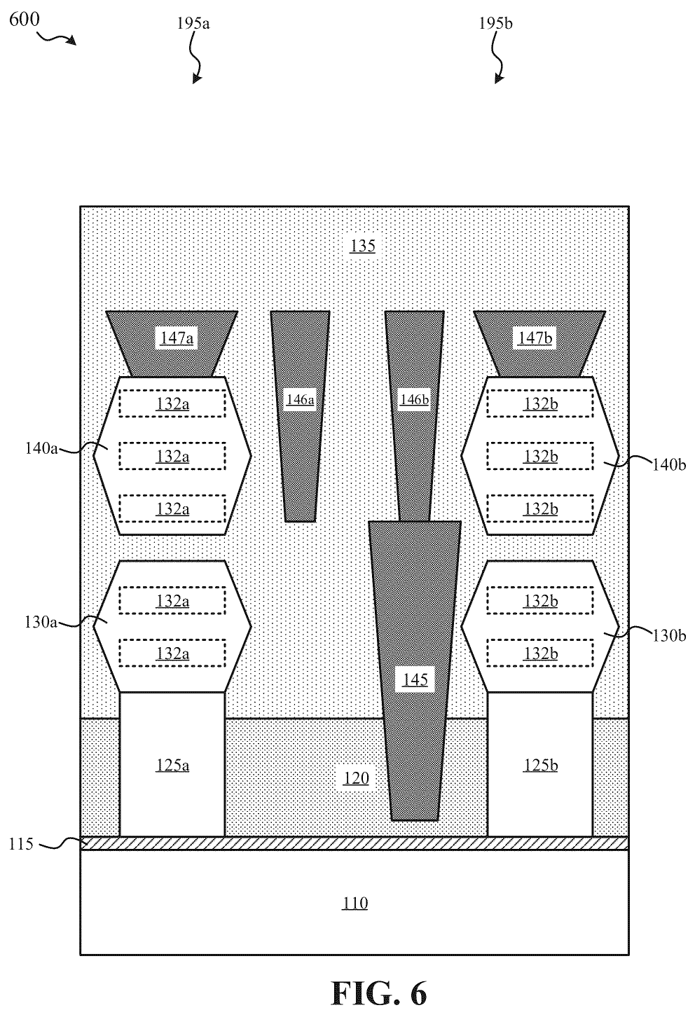

Referring to FIG. 6, a cross-sectional view of an intermediate stage 600 of forming a semiconductor structure with vertically staggered contact vias is depicted, according to some embodiments. Intermediate stage 600 includes forming contacts 147a and 147b (collectively, 147). Contacts 147 may be formed using the same/similar methods as discussed in relation to intermediate stages 300 (FIG. 3), 400 (FIG. 4), and 500 (FIG. 5). In some instances, intermediate stage 600 includes forming contacts 147 for both stacked transistor cells 195a and 195b because, similar to contact vias 146, contacts 147 may be far enough apart not to be areas of concern for shorts and/or failure points, therefore the contacts 147 may be formed together and/or using the same/similar steps for both contacts 147.

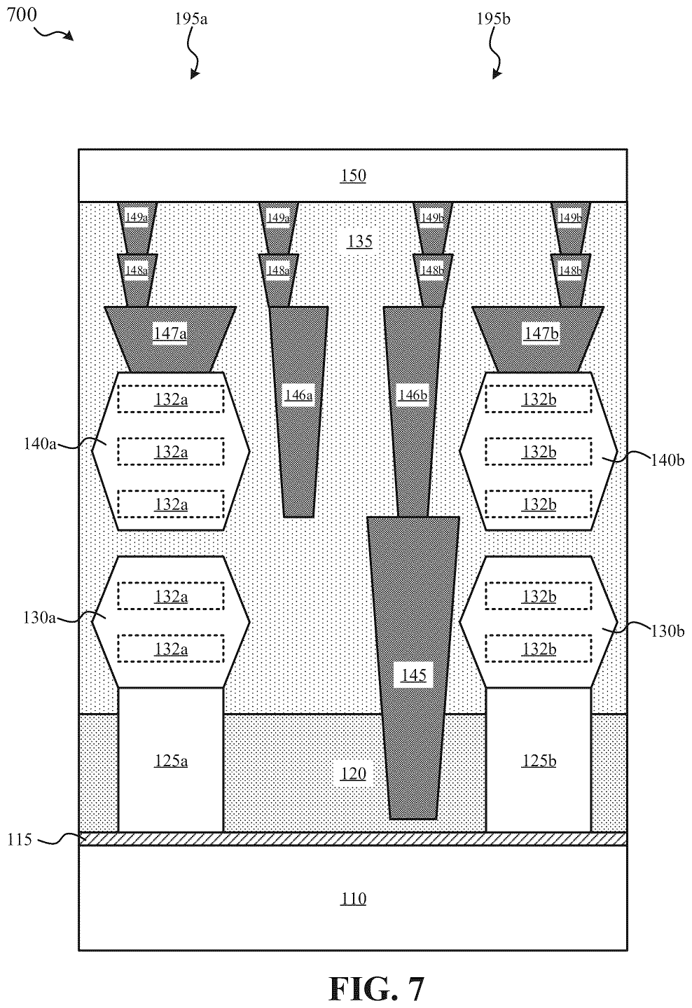

Referring to FIG. 7, a cross-sectional view of an intermediate stage 700 of forming a semiconductor structure with vertically staggered contact vias is depicted, according to some embodiments. Intermediate stage 700 includes forming contact vias 148 and conducting wires 149. Contact vias 148 and conducting wires 149 may be formed using the same/similar methods as discussed in relation to intermediate stages 300 (FIG. 3), 400 (FIG. 4), 500 (FIG. 5), and 600 (FIG. 6) (e.g., creating openings in the dielectric 135, performing a metal fill to fill the openings, removing/recessing excess metal fill, and/or filling any remaining opening with dielectric 135). In some instances, the top (when viewed from the cross-section depicted in FIG. 7) of the dielectric 135 and the conducting wires 149 may be smoothed/polished through CMP.

In some instances, intermediate stage 700 includes forming/depositing frontside interconnect 150. In some instances, frontside interconnect 150 is a back end of line (BEOL) interconnect.

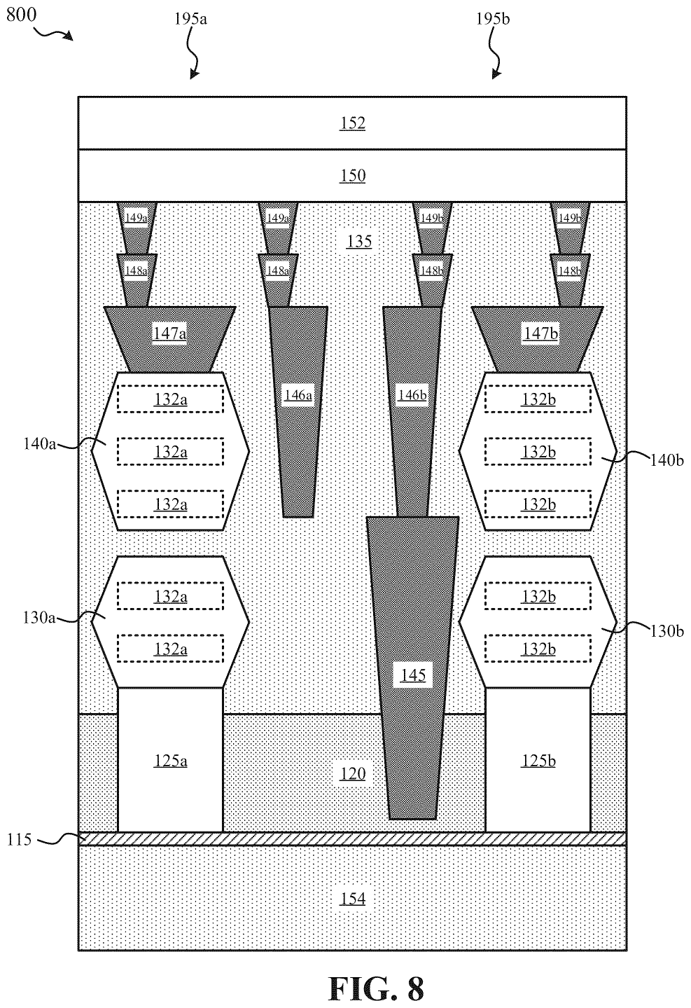

Referring to FIG. 8, a cross-sectional view of an intermediate stage 800 of forming a semiconductor structure with vertically staggered contact vias is depicted, according to some embodiments. Intermediate stage 800 includes bonding frontside interconnect 150 to a wafer 152 (for example, a carrier wafer 152). Intermediate stage 800 also includes removing substrate 110 and depositing backside interlayer dielectric (BILD) 154. In some instances, removing substrate 110 may include etching/removing up to dielectric layer 115 (as dielectric layer 115 may be an etch stop layer to help stop the etching and protect other components of the semiconductor structure from any unwanted etching). In some instances, substrate 110 may be removed through grinding, CMP, RIE, IBE, wet etch, and/or any other removal/etching process. BILD 154 may be deposited through ALD, CVD, LCVD, and/or any other deposition technique.

In some instances, prior to the removal of substrate 110 and the depositing of BILD 154, the wafer (e.g., the structure corresponding to intermediate stage 800) may be flipped. The wafer flip may occur after the bonding of frontside interconnect 150 and wafer 152, in some instances. Flipping the wafer may help access the backside of the semiconductor structure and may help with forming backside components of the semiconductor structure.

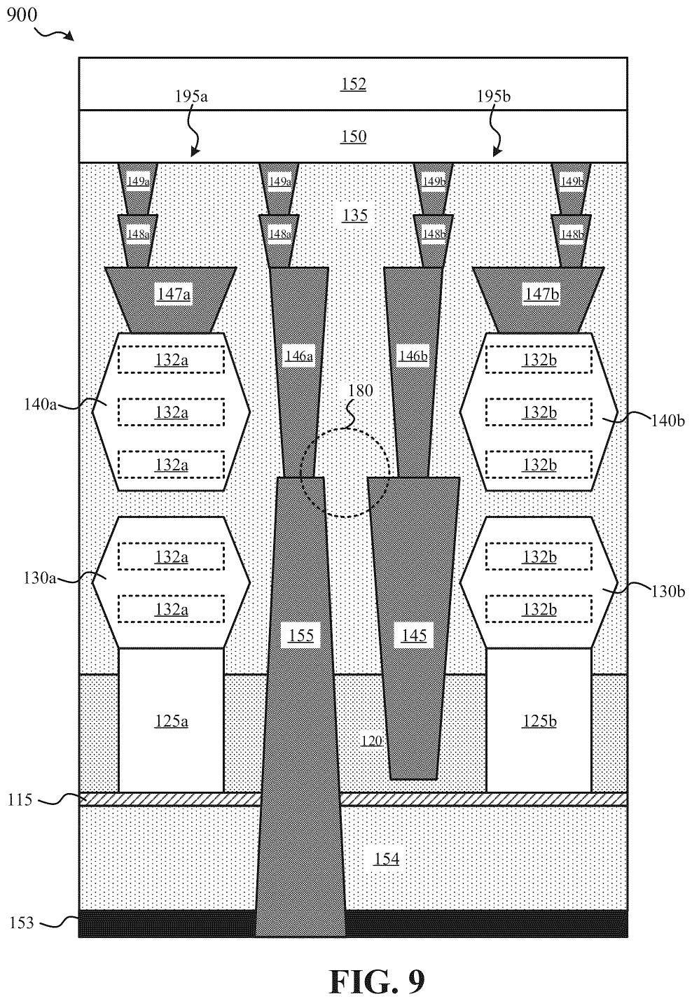

Referring now to FIG. 9, a cross-sectional view of an intermediate stage 900 of forming a semiconductor structure with vertically staggered contact vias is depicted, according to some embodiments. Intermediate stage 900 may include depositing a mask such as an organic planarization layer (OPL) 153 through, for example, ALD, CVD, LCVD, and/or any other deposition technique. OPL 153 may protect various components (such as BILD 154) from any unwanted etching.

Intermediate stage 900 may also include forming backside contact via 155. Backside contact via 155 may be formed, in some instances, by etching (for example, RIE) through portions of OPL 153, BILD 154, dielectric layer 115, dielectric 120, and dielectric 135 in order to create an opening (not depicted) for backside contact via 155. Once the opening has been created, metallization (i.e., a metal fill) may be performed in order to fill the opening with metal material(s), thus forming/creating backside contact via 155. In some instances, the metal material(s) of backside contact via 155 may be deposited/filled through ALD, CVD, LCVD, and/or any other deposition/fill technique. In some instances, backside contact via 155 may be formed using the same/similar methods as discussed in relation to intermediate stages 300 (FIG. 3), 400 (FIG. 4), 500 (FIG. 5), 600 (FIG. 6), and 700 (FIG. 7).

Backside contact via 155 is a contact via formed through/in the backside of the semiconductor structure. This way, backside contact via 155 is an inverted contact (for example, compared to the orientation of contact 145). By inverting backside contact via 155, the area 180 is not a failure point as backside contact via 155 and contact via 145 are far enough apart to not cause any shorts.

In some instances, as depicted in FIG. 9, backside contact via 155 is only formed in one of the adjacent stacked transistor cells 195 (in this instance, stacked transistor cell 195a). By only forming a backside contact via 155 in one of the adjacent stacked transistor cells 195, the adjacent stacked transistor cells 195 have one or more contact vias (in this instance, contact via 145 and backside contact via 155) that have different orientations, with one having an orientation that is flipped/inverted compared to the other. As discussed herein, this helps prevent failure points and shorts.

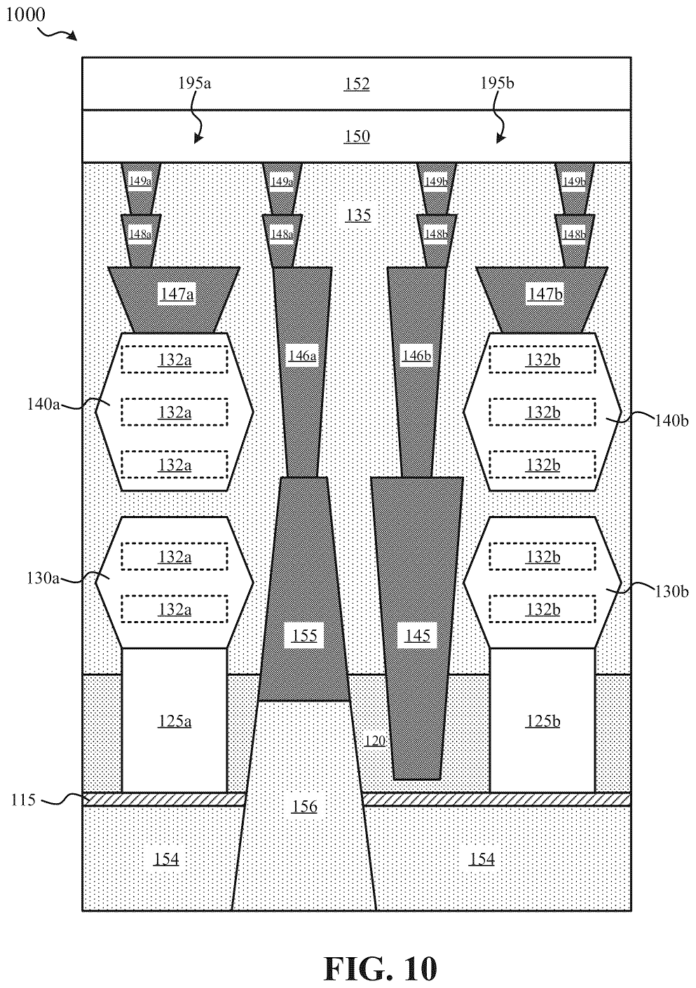

Referring to FIG. 10, a cross-sectional view of an intermediate stage 1000 of forming a semiconductor structure with vertically staggered contact vias is depicted, according to some embodiments. Intermediate stage 1000 may include recessing backside contact via 155. In some instances, the metal fill/metallization from intermediate stage 900 may have filled the entire opening with metal material(s), however backside contact via 155 may not need to extend all the way through the various dielectric/dielectric layers (e.g., 120, 115, and 154). Therefore, a portion of backside contact via 155 may be recessed in order to remove excess material. In some instances, backside contact via 155 is recessed (i.e., a portion of backside contact via 155 is removed) through patterning/etching processes such as RIE, IBE, and/or any other patterning/etching process. In some instances, backside contact via 155 may be recessed to a contact thickness (when viewing from the cross-section depicted in FIG. 10) smaller than the contact thickness of contact via 145.

In some instances, intermediate stage 1000 further includes filling the remining opening (for example, after the recessing) with dielectric 156. In some instances, dielectric 156 may be the same/similar material(s) as dielectric 154. The dielectric 156 may be deposited/filled through ALD, CVD, LCVD, and/or any other deposition/fill technique. In some instances, although dielectric 156 is depicted as a separate entity to other dielectric (for example, dielectric 154), the dielectrics may not be separate entities.

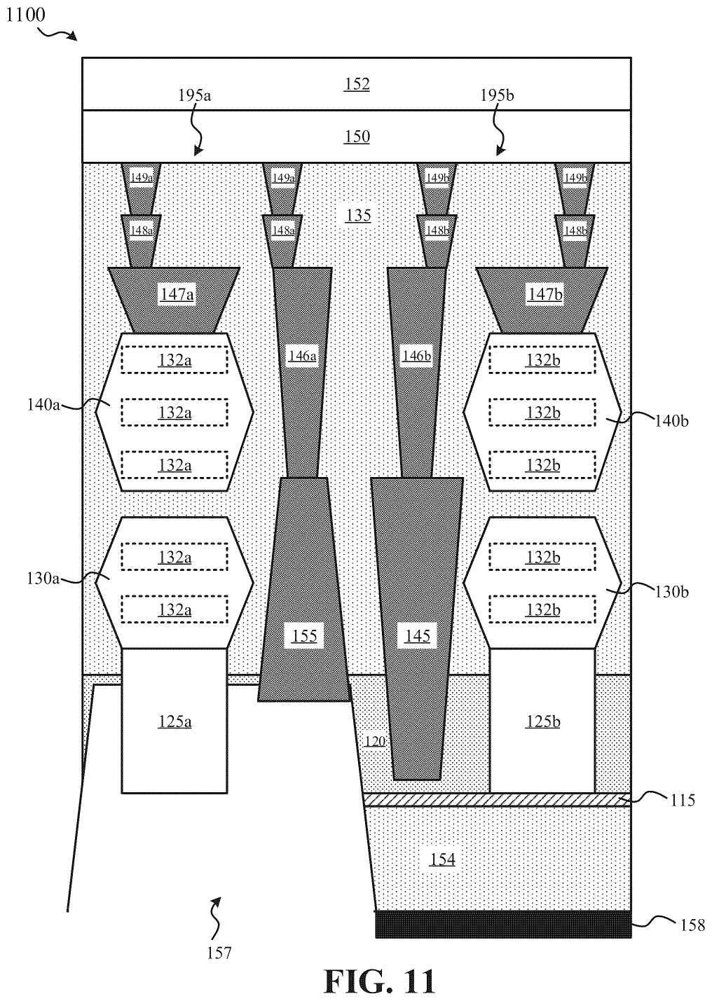

Referring to FIG. 11, a cross-sectional view of an intermediate stage 1100 of forming a semiconductor structure with vertically staggered contact vias is depicted, according to some embodiments. Intermediate stage 1100 includes patterning/forming an opening 157 in the stacked transistor cell 195a region of the semiconductor structure. This opening 157 may create space for forming a backside contact (discussed further herein). In some instances, a selective etching technique (such as RIE) may be used in order to remove the dielectric material(s) of dielectric 120, dielectric layer 115, dielectric 154, and dielectric 156 without removing backside contact via 155 and/or dummy contact 125a.

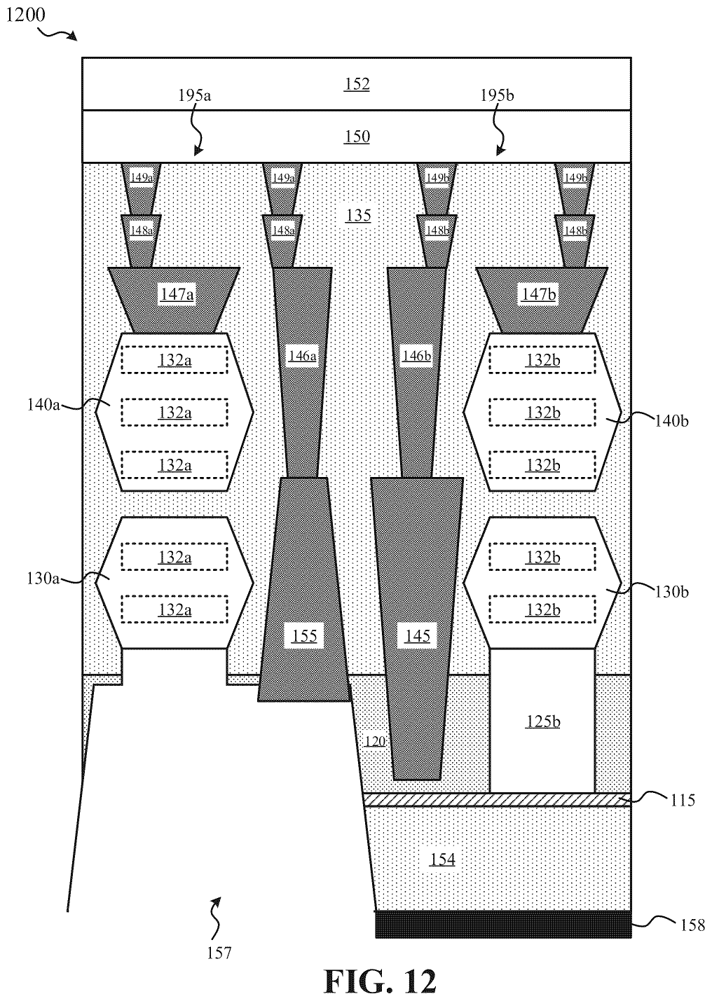

Referring to FIG. 12, a cross-sectional view of an intermediate stage 1200 of forming a semiconductor structure with vertically staggered contact vias is depicted, according to some embodiments. In intermediate stage 1200, dummy contact 125a is removed, thus extending the opening 157 to bottom epi 130a. In some instances, dummy contact 125a may be removed using a selective wet etch or dry etch process. In some instances, dummy contact 125a may be removed using RIE, IBE, and/or any other etching/removal technique(s).

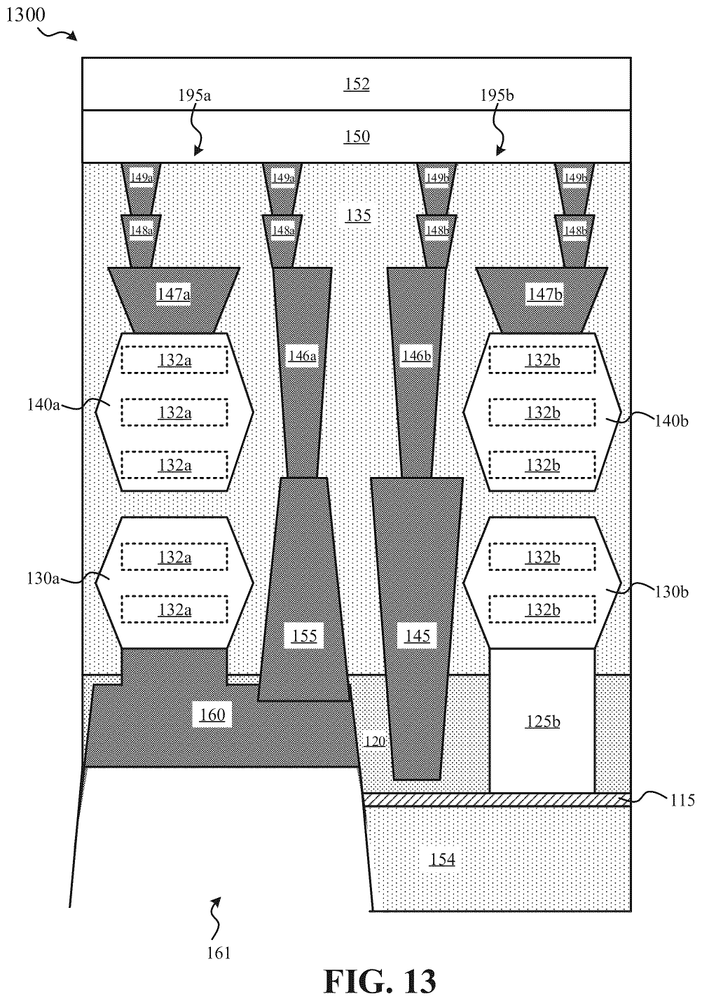

Referring to FIG. 13, a cross-sectional view of an intermediate stage 1300 of forming a semiconductor structure with vertically staggered contact vias is depicted, according to some embodiments. Intermediate step 1300 includes a metal fill to fill the opening 157 with metal material(s) 160, thus forming backside contact 160. In some instances, as depicted in FIG. 13, intermediate stage 1300 further includes recessing backside contact 160 (for example, through patterning/etching processes such as RIE, IBE, and/or any other patterning/etching process). Recessing backside contact 160 may help stagger backside contact 160 so that it is not directly in line with the later formed backside contact for stacked transistor cell 195b (discussed further herein). Recessing backside contact 160 may result in an opening 161 below the backside contact 160.

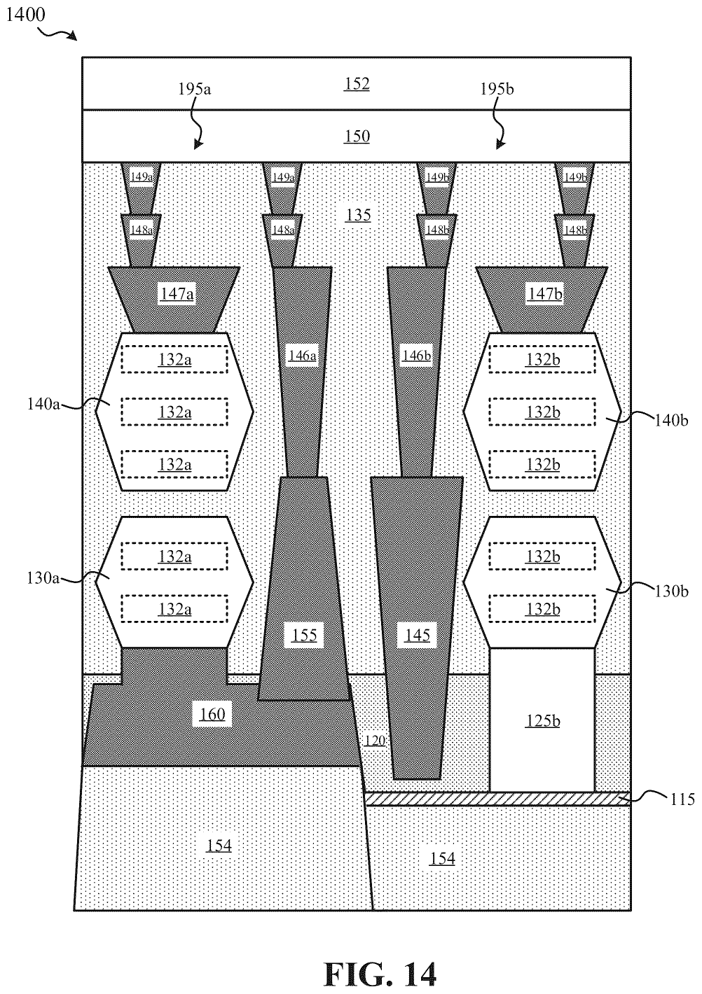

Referring to FIG. 14, a cross-sectional view of an intermediate stage 1400 of forming a semiconductor structure with vertically staggered contact vias is depicted, according to some embodiments. Intermediate stage 1400 includes filling the opening 161 with dielectric 154 (for example, through ALD, CVD, LCVD, etc.). In some instances, CMP is performed to polish/smooth the exposed surface(s) of the dielectric 154.

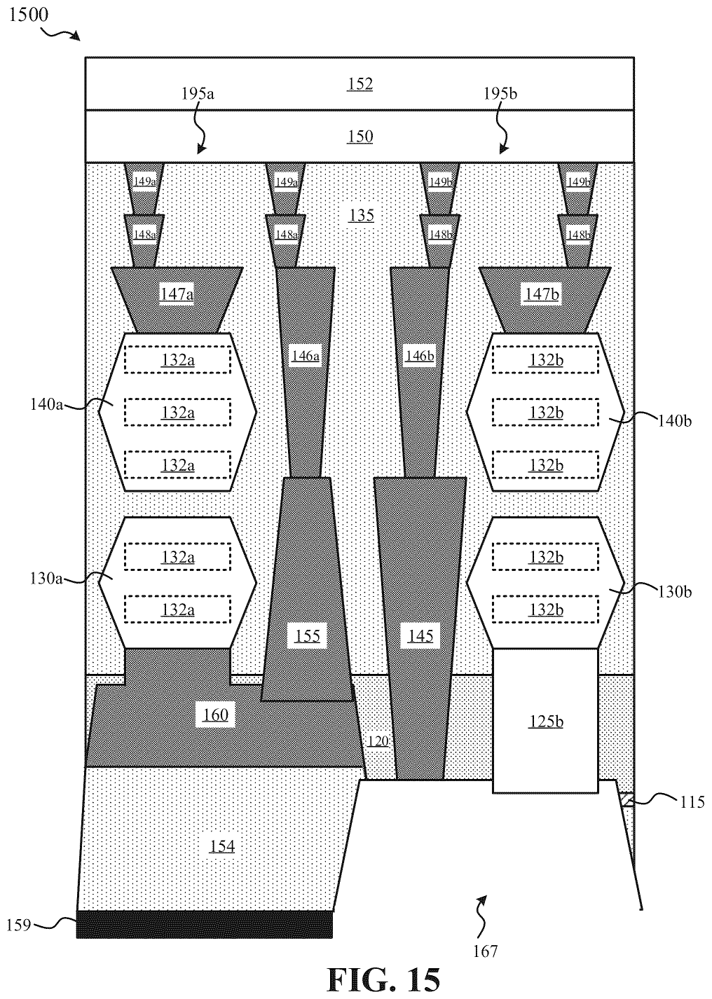

Referring to FIG. 15, a cross-sectional view of an intermediate stage 1500 of forming a semiconductor structure with vertically staggered contact vias is depicted, according to some embodiments. In some instances, intermediate stage 1500 includes depositing a mask, such as OPL 159, to protect dielectric 154 in the stacked transistor cell 195a region of the semiconductor structure from any unwanted etching.

Intermediate stage 1500 may also include patterning/forming an opening 167 in the stacked transistor cell 195b region of the semiconductor structure. This opening 167 may create space for forming a backside contact for stacked transistor cell 195b (discussed further herein). In some instances, a selective etching technique (such as RIE) may be used to create the opening 167 without removing dummy contact 125b.

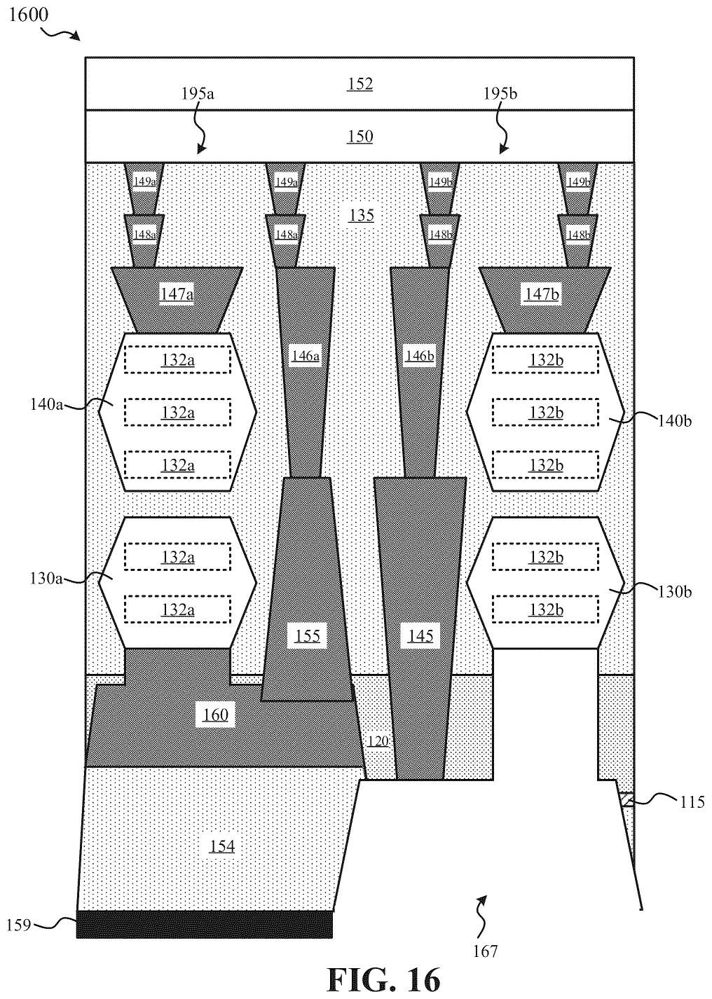

Referring to FIG. 16, a cross-sectional view of an intermediate stage 1600 of forming a semiconductor structure with vertically staggered contact vias is depicted, according to some embodiments. In intermediate stage 1600, dummy contact 125b is removed, thus extending the opening 167 to bottom epi 130b. In some instances, dummy contact 125b may be removed using a selective wet etch or dry etch process. In some instances, dummy contact 125a may be removed using RIE, IBE, and/or any other etching/removal technique(s).

To finish forming semiconductor structure 100 (FIG. 1) from intermediate stage 1600 (FIG. 16), opening 167 may be filled with metal material(s) to form backside contact 170 (FIG. 1). In some instances, the exposed edges of dielectric 154 and backside contact 170 may be smoothed/polished through CMP. In some instances, the CMP process may also remove OPL 159. In some instances, OPL 159 may be removed through, for example, RIE, IBE, and/or any other removal/etching process.

Referring to FIG. 17, a cross-sectional view of an example semiconductor structure 1700 with vertically staggered contact vias is depicted, according to some embodiments. Semiconductor structure 1700 includes backside contact via 155 that is flipped/inverted (for example, when compared to the orientation of contact via 145). This helps prevent area 1780 from being a failure point as backside contact via 155 and contact via 145 are far enough apart to prevent shorting. In semiconductor structure 1700 the same stacked semiconductor cell 1795a includes the inverted backside contact via 155 as well as the backside contact 1760 with a taller/larger contact thickness 1799. Stacked semiconductor cell 1795b includes a non-inverted contact via 145 as well as a backside contact 1770 with a smaller contact thickness 1798 (compared to backside contact 1770). This helps vertically stagger backside contacts 1760 and 1770 from each other, thus distancing backside contacts 1760 and 1770 and preventing area 1790 from becoming a failure point.

Referring to FIG. 18, a cross-sectional view of an example semiconductor structure 1800 with vertically staggered contact vias is depicted, according to some embodiments. In some instances, as depicted in semiconductor structure 1800, various contacts/contact vias (e.g., contact vias 1846a and b, contact via 1855, and contact via 1845 may be separated by dielectric 135 as well as the top and bottom epis (140b and 130b, respectively). In this instance, there may not be any areas of concern between contact vias 1855 and 1845, therefore neither contact via 1855 nor 1845 need to be inverted. However, backside contacts 160 and 170 may remain vertically staggered in order to prevent area 1880 from becoming a failure point.

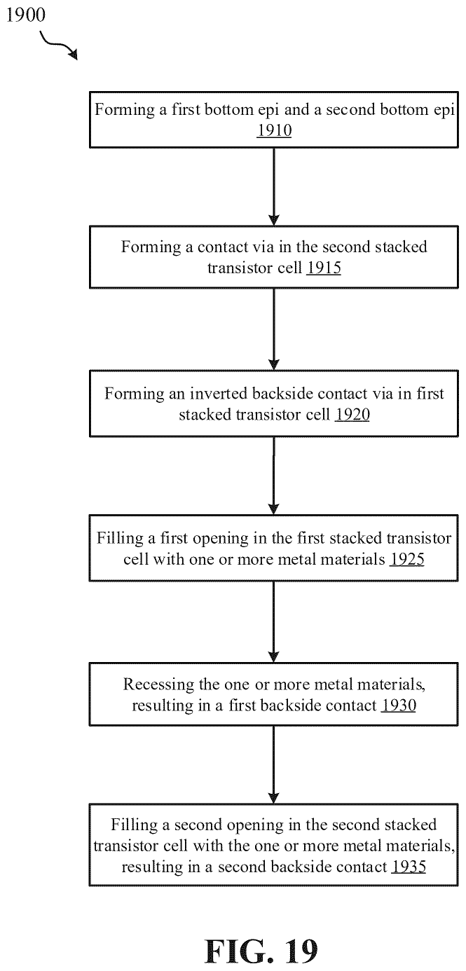

Referring to FIG. 19, a flowchart of an example method 1900 of forming a semiconductor structure (for example, semiconductor structure 100 (FIG. 1), semiconductor structure 1700 (FIG. 17), and/or semiconductor structure 1800 (FIG. 18)) with vertically staggered contact vias is depicted, according to some embodiments. In some instances, method 1900 may correspond to intermediate stages 200-1600 (FIGS. 2-16).

Method 1900 includes operation 1910 of forming a first bottom epi and a second bottom epi. This may correspond to FIG. 2, in some instances. In some instances, a first stacked transistor cell includes the first bottom epi and a second stacked transistor cell includes the second bottom epi. In some instances, a first top epi (in the first stacked transistor cell) and a second top epi (in the second stacked transistor cell) may also be formed.

As discussed herein, there are instances when the stacked transistor structure(s) include a contact via (such as contact via 145) and, in some instances, an inverted backside contact via (such as inverted backside contact via 155). In these instances, method 1900 may include operation 1915 of forming a contact via in the second stacked transistor cell. In some instances, forming the contact via in the second stacked transistor cell (e.g., stacked transistor cell 195b) may correspond to intermediate stages 300 (FIG. 3) and/or 400 (FIG. 4). For example, in some instances, forming the contact via may include patterning/etching an opening in one or more layers of dielectric, filling the opening with one or more metal materials, and recessing the one or more metal materials, resulting in the contact via.

In some instances, when the stacked transistor structure includes an inverted backside contact via (such as inverted backside contact via 155), method 1900 may include operation 1920 of forming an inverted backside contact via in the first stacked transistor cell. This may correspond to intermediate stages 900 (FIG. 9) and/or 1000 (FIG. 10), in some instances. In some instances, forming the inverted backside contact via in the first stacked transistor cell (e.g., stacked transistor cell 195a), may include patterning/etching an opening in one or more layers of dielectric (the opening patterned/etched through a backside of the stacked transistor cell), filling the opening with one or more metal materials, and recessing the one or more metal materials, resulting in an inverted backside contact via. In some instances, the inverted backside contact via may have an inverted orientation compared to the orientation of the contact via formed in operation 1915.

In some instances, as discussed herein, the wafer/semiconductor structure may be flipped prior to the formation of the inverted backside contact via (for example, after operation 1915 but before operation 1920). This may help form inverted backside contact via (as well as the backside contacts) in/through the backside of the semiconductor structure.

Method 1900 includes operation 1925 of filling an opening in the first stacked transistor cell with one or more metal materials. In some instances, the first opening is in a backside of the first transistor cell. Operation 1925 may correspond to intermediate stages 1100 (FIG. 11), 1200 (FIG. 12), and/or 1300 (FIG. 13), in some instances. In some instances, the opening may be opening 157 (FIGS. 11 and/or 12).

Method 1900 includes operation 1930 of recessing the one or more metal materials, resulting in a first backside contact (for example, backside contact 160 (FIGS. 1, 13, etc.). In some instances, operation 1930 may correspond to intermediate stage 1300 (FIG. 13). In some instances, as depicted in FIG. 13, the first backside contact (e.g., backside contact 160 (FIGS. 1 and/or 19), 1760 (FIG. 17), etc.) is directly connected to the first bottom epi (e.g., bottom epi 130a). In some instances, the first backside contact has a first contact thickness, such as contact thickness 198 depicted in FIG. 1.

Method 1900 includes operation 1935 of filling a second opening in the second stacked transistor cell with the one or more metal materials, resulting in a second backside contact. In some instances, the second opening is in a backside of the second stacked transistor cell. Operation 1935 may correspond to intermediate stages 1500 (FIG. 15) and 1600 (FIG. 16) as well as fully formed semiconductor structure(s) 100 (FIG. 1), 1700 (FIG. 17), and/or 1800 (FIG. 18). In some instances, the second opening may correspond to opening 167 (FIG. 16), the second stacked transistor cell may correspond to stacked transistor cell 195b, and/or the second backside contact may correspond to backside contact 170 (FIGS. 1 and/or 18) and/or 1770 (FIG. 17).

In some instances, as depicted in FIG. 1, the second backside contact is directly connected to the second bottom epi (e.g., bottom epi 130b). In some instances, the second backside contact may have a second contact thickness (for example, contact thickness 199 (FIG. 1)) larger/taller than the first contact thickness (for example, contact thickness 198 (FIG. 1)).

In some instances, method 1900 may include additional steps not depicted in FIG. 19. For example, method 1900 may include any of the intermediate stages (e.g., 200-1600 (FIGS. 2-16)) discussed herein in relation to forming semiconductor structure 100 (FIG. 1), semiconductor structure 1700 (FIG. 17), and/or semiconductor structure 1800 (FIG. 18).

The present invention may be a system, a method, a computer program product, etc. at any possible technical detail level of integration.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks. The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to some embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, wherein the semiconductor structure comprises:
a first stacked transistor cell, the first stacked transistor cell comprising a first backside contact and the first backside contact having a first contact thickness; and
a second stacked transistor cell, the second stacked transistor cell comprising a second backside contact, the second backside contact having a second contact thickness different from the first contact thickness.

2. The semiconductor structure of claim 1, wherein:
the second stacked transistor cell is adjacent to the first stacked transistor cell.

3. The semiconductor structure of claim 1, wherein:
the first stacked transistor cell further comprises an inverted backside contact via in a first orientation;
the second stacked transistor cell further comprises a contact via in a second orientation; and
the first orientation is inverted compared to the second orientation.

4. The semiconductor structure of claim 3, wherein the contact via is a frontside contact via.

5. The semiconductor structure of claim 3, wherein:
the inverted backside contact via is directly connected to the first backside contact; and
the contact via is directly connected to the second backside contact.

6. The semiconductor structure of claim 3, wherein:
the inverted backside contact via is directly connected to a second contact via, the second contact via having a third orientation; and
the third orientation is a same orientation as the second orientation.

7. The semiconductor structure of claim 1, wherein the second contact thickness is smaller than the first contact thickness.

8. The semiconductor structure of claim 1, wherein the second contact thickness is larger than the first contact thickness.

9. The semiconductor structure of claim 1, wherein:
the first stacked transistor cell further comprises a first top epi and a first bottom epi; and
the second stacked transistor cell further comprises a second top epi and a second bottom epi.

10. The semiconductor structure of claim 9, wherein:
the first backside contact is directly connected to the first bottom epi; and
the second backside contact is directly connected to the second bottom epi.

11. The semiconductor structure of claim 1, wherein the first transistor cell and the second transistor cell further comprise one or more nanosheets.

12. A system, wherein the system comprises:
a semiconductor structure, wherein the semiconductor structure comprises:
a first stacked transistor cell, the first stacked transistor cell having a first contact thickness, wherein the first stacked transistor cell comprises a first backside contact, a first bottom epi, and a first top epi, and wherein the first backside contact is directly connected to the first bottom epi; and
a second stacked transistor cell, the second stacked transistor cell having a second contact thickness larger than the first contact thickness, wherein the second transistor cell comprises a second backside contact, a second bottom epi, and a second top epi, and wherein the second backside contact is directly connected to the second bottom epi.

13. The system of claim 12, wherein:
the first stacked transistor cell further comprises an inverted backside contact via in a first orientation;
the second stacked transistor cell further comprises a contact via in a second orientation; and
the first orientation is inverted compared to the second orientation.

14. The system of claim 13, wherein the contact via is a frontside contact via.

15. The system of claim 13, wherein:
the inverted backside contact via is directly connected to the first backside contact; and
the contact via is directly connected to the second backside contact.

16. The system of claim 15, further comprising:
an interconnect, wherein the bottom epi is connected to the interconnect through at least the first backside contact and the inverted backside contact.

17. The system of claim 13, wherein:
the inverted backside contact via is directly connected to a second contact via, the second contact via having a third orientation; and
the third orientation is a same orientation as the second orientation.

18. The system of claim 12, wherein:
the first stacked transistor cell further comprises a contact via in a first orientation;
the second stacked transistor cell further comprises an inverted backside contact via in a second orientation; and
the second orientation is inverted compared to the first orientation.

19. The system of claim 18, wherein:
the contact via is directly connected to the first backside contact; and
the inverted backside contact is directly connected to the second backside contact.

20. A method of forming a semiconductor structure, the method comprising:
forming a first bottom epi and a second bottom epi, wherein a first stacked transistor cell comprises the first bottom epi and a second stacked transistor cell comprises the second bottom epi;
filling a first opening in the first stacked transistor cell with one or more metal materials;
recessing the one or more metal materials, resulting in a first backside contact directly connected to the first bottom epi, the first backside contact having a first contact thickness; and
filling a second opening in the second stacked transistor cell with the one or more metal materials, resulting in a second backside contact directly connected to the second bottom epi, wherein the second backside contact has a second contact thickness larger than the first contact thickness.
